(19) United States
(12) Patent Application Publication
(10) Pub. No.: US 2018/0005863 A1
(43) Pub. Date: Jan. 4, 2018

(54) MINIMAL CONTACT END-EFFECTORS FOR HANDLING MICROELECTRONIC DEVICES

(71) Applicant: INTEL CORPORATION, Santa Clara, CA (US)

(72) Inventors: DANIEL CHAVEZ-CLEMENTE, Phoenix, AZ (US); ADAM J. BAWDEN, Gilbert, AZ (US); BASSAM M. ZIADEH, Gilbert, AZ (US)

(21) Appl. No.: 15/543,218

(22) PCT Filed: Jan. 7, 2016
(86) PCT No.: PCT/US2016/012524

§ 371 Date: Jul. 12, 2017

Related U.S. Application Data
(60) Provisional application No. 62/102,456, filed on Jan. 12, 2015.

(51) Int. Cl. H01L 21/683; G01B 11/27; H01L 21/67; H01L 21/68

(52) U.S. Cl. CPC H01L 21/6838; H01L 21/681; G01B 11/272; H01L 21/67144; H01L 21/67259

(57) ABSTRACT

A minimal contact end-effector is described that may be used for handling microelectronic and similar types of devices. In one example the end-effector has a vacuum pad to generate a lifting force and a standoff fastened to the vacuum pad. The standoff has a plurality of legs with chamfered edges to contact the edges of a microelectronic device to hold the device against the lifting force.

### CROSS-REFERENCE TO RELATED APPLICATIONS

This application claims priority to U.S. Provisional Application Ser. No. 62/102,456, filed Jan. 12, 2015, entitled Minimal Contact End-Effectors for Handling Integrated Circuit Products by Daniel Chavez-Clemente et al.

### FIELD

The present description relates to end-effectors for handling microelectronic devices and, in particular, to an end-effector with a minimal contact area on the device.

### BACKGROUND

Microelectronic devices, such as processors, controllers, memory, interfaces, inertial sensors, and other mechanical devices are typically produced in groups on a wafer. The wafer provides a substrate upon which the devices are produced and a convenient surface to move and carry all of the devices during fabrication. At some stage in the fabrication of the devices on the wafer, the wafer is diced to separate all of the devices from each other. This results in a large number of small, lightweight, and fragile devices.

The further assembly of the devices uses several automated pick and place operations at various stages of the flow. The current pick and place process requires a handling Keep Out Zone (KOZ) on the substrate of each device. This zone is reserved for these pick and place operations, because many pick and place machines use rubber suction cups to handle the product. The suction cup requires a smooth, flat, surface large enough for the suction cup to obtain a firm grip on the device. After the pick and place operations are finished, this KOZ is wasted space on the final product, since no components or die can be placed within it. Some pick and place machines avoid the need for a KOZ but at the risk of die staining or cracking.

### BRIEF DESCRIPTION OF THE DRAWINGS

Embodiments are illustrated by way of example, and not by way of limitation, in the figures of the accompanying drawings in which like reference numerals refer to similar elements.

FIG. 1 is a diagram of a die or a chip with a backside top surface to show different grip surfaces according to an embodiment.

FIG. 2 is an exploded view isometric diagram of an example of a gripper for a single die according to an embodiment.

FIG. 3 is an assembled isometric view diagram of the top side of the gripper of FIG. 2 according to an embodiment.

FIG. 4 is an assembled isometric view diagram of the bottom side of the gripper of FIG. 2 according to an embodiment.

FIG. 5 is an isometric view of a variety of different types and configurations of vacuum pads according to an embodiment.

FIG. 6 is an isometric diagram of a standoff as seen from above according to an embodiment.

FIG. 7 is an isometric diagram of the standoff of FIG. 6 as seen from above according to an embodiment.

FIG. 8 is a cross-sectional side view diagram of the standoff FIG. 6 with a vacuum pad holding a substrate according to an embodiment.

FIG. 9 is an isometric diagram of an alternative standoff for smaller dies as seen from below according to an embodiment.

FIG. 10 is a side cross-sectional view of a vacuum pad and a standoff showing an alternative quick-release mechanism according to an embodiment.

FIG. 11 is an enlarged side cross-sectional view of the quick-release mechanism of FIG. 10 according to an embodiment.

FIG. 12 is a diagram of a fiber optic sensor according to an embodiment.

FIG. 13 is a diagram of a flat LED reflective sensor according to an embodiment.

FIG. 14 is a graph of different sensor calibration curves for different possible die surfaces according to an embodiment.

FIG. 15 is a side view diagram of a pick and place system using standoffs according to an embodiment.

FIG. 16 is an isometric view of another alternative standoff according to an embodiment.

FIG. 17 is an isometric view of another alternative standoff according to an embodiment.

FIG. 18 is a top isometric view of a set of six standoffs in an interlaced configuration according to an embodiment.

FIG. 19 is a bottom isometric view of the standoffs of FIG. 18 according to an embodiment.

FIG. 20 is a block diagram of an example computing system according to an embodiment.

### DETAILED DESCRIPTION

Methods and apparatus presented here relate to Bernoulli and cyclone end effectors or a non-contact, pick and place gripper with a minimal Zero Keep Out Zone on devices. Applications may be found in test systems and in design and debug tools. A Bernoulli vacuum pad uses pressurized air or gas and the Bernoulli Effect to draw an item toward the vacuum pad. A cyclone vacuum pad uses a swirling column of air or other gas to draw the item toward the vacuum pad.

As described, products are handled with zero Keep Out Zone without the need to touch the die or the top of the substrate. This is accomplished by means of a vacuum pad to generate a lifting force and a chamfered standoff that makes minimal contact with the edges of the substrate. The described approach provides a variety of different major advantages, depending on the implementation.

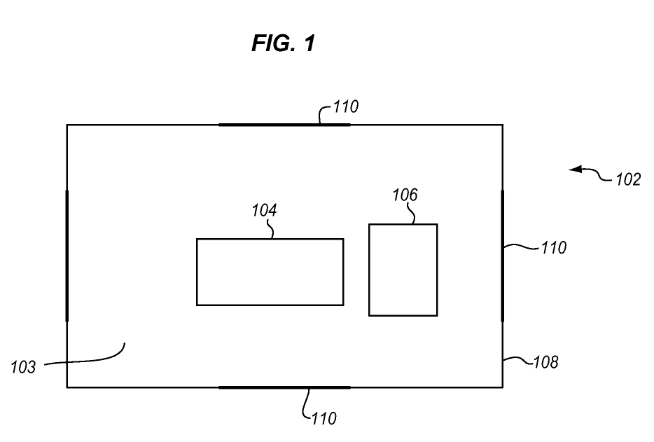

FIG. 1 is a diagram of a die 102 with a backside top surface 103. The active circuitry is formed on the opposite front side (not shown). There is a KOZ 104 in the center of the back side of the die reserved for a vacuum gripping tool. The KOZ is as large as the vacuum tool rubber suction cup plus some additional area for placement errors. No other devices may be placed in this area and this area may be contaminated with materials from the rubber suction cup and the vacuum tool. A secondary KOZ 106 may also be reserved for other types of tools or other parts of the first tool. While the KOZ must be reserved through the design, it is not physically marked on the die. As an alternative, the tool described herein uses contact with the edge 108 of the die. In this example there are four edge locations 110, one on each side of the die that will make physical contact with the die. The entire backside of the die may then be used for vias, passives, coatings, and other purposes.

While the example herein are described in the context of a die, the same standoff and handling principles may be applied to a packaged die or a chip. The package may have one or more dies inside. The same edge gripping standoff may be used to handle larger devices. The die may be of any desired types and may be formed in silicon, or any of a variety of other materials. A die, package, chip, or other small part is referred to generally herein as a microelectronic device.

Elimination of the KOZ also allows form factor shrinkage of top-side-limited products, which can be a competitive advantage for smaller dies particularly in the mobile market and form memory dies. It also enables simplification of substrate design rules, making the product design process leaner. In addition, picking without touching the die helps prevent yield loss due to staining or cracking.

The described gripper assembly provides an extremely short lead time for new types of dies because the adapters for different die form factors can be 3D-printed. This results in very high agility when a new form factor is introduced. The described gripper also carries significant cost savings because it does not require rubber cups, which must be replaced as they wear out. Using 3D printing or additive manufacturing, the adapter is formed of a single integral piece of material which reduces breakage. For higher volumes, injection molding, casting, and other techniques may be used.

The described gripper makes use of positive pressure to generate a lifting force on the unit via a vortex (cyclone) or Bernoulli principle (similar to a Venturi tube). In order to keep the part stable during the motion of the pick and place head, a standoff appropriate to the specific form factor of each type of die is fitted onto the assembly by means of a quick release mechanism. This standoff makes only minimal contact along the edges of the part and requires no real estate on the substrate itself.

The presence of the part that is being gripped may be detected via a reflective sensor embedded in the gripper with sensitivity that can be tuned in software and hardware. The final result is a gripper that can pick and place parts with zero KOZ, with comparable accuracy to existing methods, and without any risk of damaging the die.

The existing pick and place solutions for microprocessor assembly fall into two categories: (a) pick on substrate via rubber cups, (b) pick on die. The first category requires a handling KOZ to accommodate suction cups, and therefore cannot be used to handle products with zero KOZ. The second category is able to deal with zero KOZ, but carries an inherent risk of producing yield loss due to die staining or cracking. The gripper design described herein improves on both of these because it does not require a handling KOZ, and it is able to handle the product without touching the top of the die.

Additionally, the new gripper results in significant cost reduction because it does not require any suction cups, which must be replaced over time. Finally, the new design greatly reduces the lead time for new die form factors. The only thing that changes from one form factor to another is the standoff, which can be designed internally and fabricated via 3D printing. With this technology it is even possible to reduce the need for spare standoffs kept in stores, as they can be printed on-demand with a 3D printer.

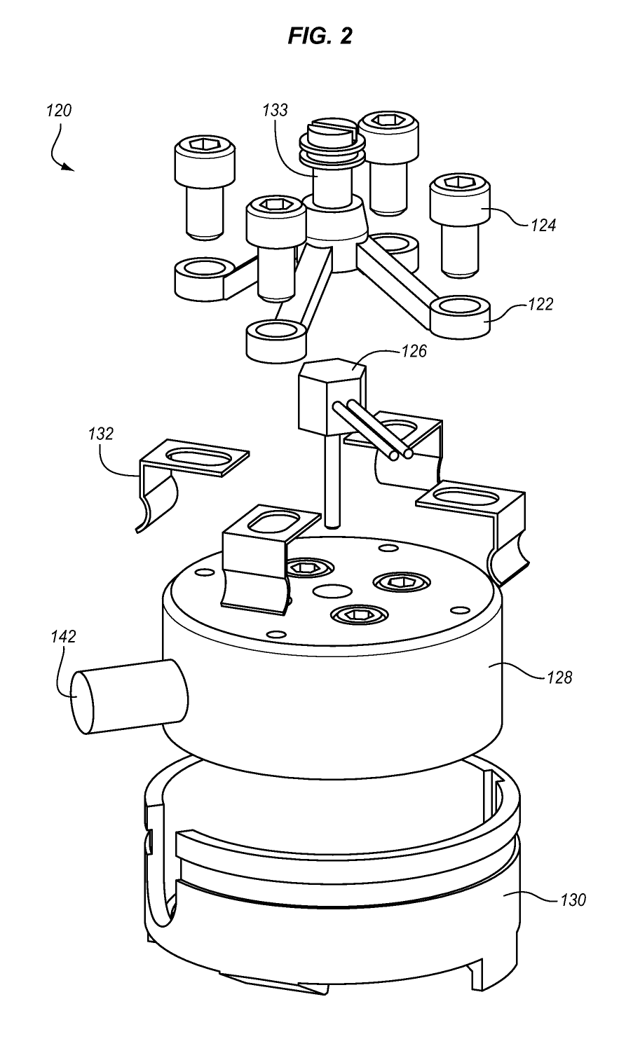

FIG. 2 is an exploded view isometric diagram of an example of a gripper for a single die. The gripper 120 in this example has at least 4 main parts: a mating adapter 122, a part detection sensor 126, a vacuum pad 128, and a standoff 130. A shaft 133 at the top of the mating adapter enables the gripper to be mounted to a pick and place tool (not shown) and provides support for the sensor. The shaft 133 of the mating adapter 122 and the sensor 126 attach to the top of the vacuum pad, which may be an off-the-shelf positive pressure pad working on either a Bernoulli principle, cyclone principle, or any other similar principle. Cyclone pads produce the necessary forces with very low OFA pressures. The standoff attaches to the vacuum pad in this example by means of a quick release mechanism 132, and supports the part during pickup and transport. The standoff 130 enables minimal contact with the substrate of the die (not shown), as described in more detail below.

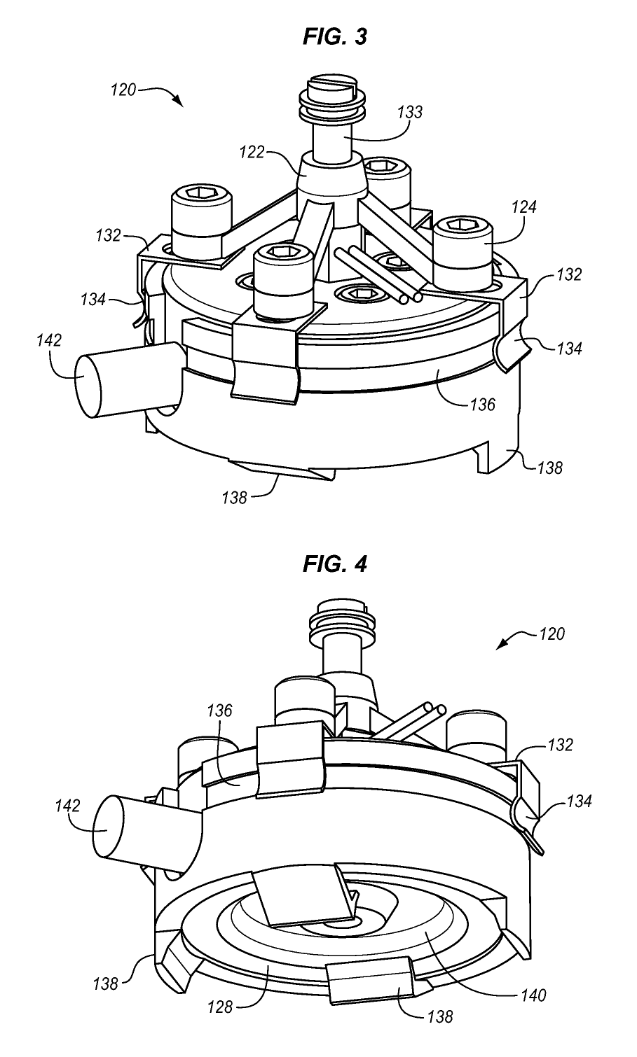

FIG. 3 is an assembled isometric view diagram of the top side of the gripper 120 of FIG. 2 showing the vacuum pad 128 fastened to or held in place within the standoff 130. The quick release mechanism 132 in the form of spring clips are attached at one end to the vacuum pad with the screws 124. The other end of each spring clip has a tab 134 which engages a groove 136 in the standoff 130 to secure the standoff against the vacuum pad. The standoff may be configured to attach to any of a variety of different vacuum pad designs. While the standoff is shown as surrounding and enclosing the vacuum pad when attached, the particular connection between the vacuum pad and the standoff may be adapted to suit different vacuum pads and different dies.

FIG. 4 is an assembled isometric view diagram of the bottom side of the gripper 120 of FIG. 2 showing the underside of the standoff. The bottom side of the vacuum pad 128 has an air chamber 140 within which a pressure differential is created using compressed air that is supplied through one or more air fittings 142. The standoff 130 surrounds the air chamber and allows the vacuum pad to operate according to the particular design principle of the vacuum pad. The standoff has a set of legs 138 that serve as edge contactors formed integrally at the bottom surface of the standoff. The standoff has an opening in the main body between the four legs that allows the air chamber at the bottom of the vacuum pad to generate its lifting force on a die below the standoff.

The legs are configured to match the dimensions of the die for which the standoff is designed. Each leg has a chamfered edge as described below that contacts an edge of the die to retain the die in a specific position adjacent the vacuum pad air chamber. Here it can be seen that the legs are configured for a rectangular die. Two opposite legs extend straight down from the edge of the standoff for the long ends of the die. The other two opposite legs extend in towards the center of the standoff to contact the narrow sides of the die.

### Vacuum Pad

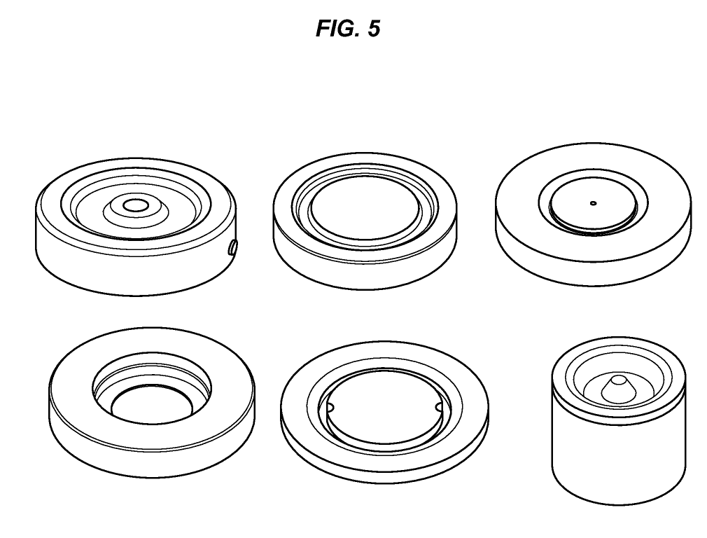

Different vacuum pads may be used to generate lifting forces. These include Bernoulli pads and “cyclone” pads. Both of these are off-the-shelf, low cost components which operate with positive airflow to generate a low pressure area on top of the part and thus a lifting force. The pads are available in thin and thick versions, and the described gripper design can accommodate both depending on the application. Thin pads are appropriate for tools with limited space to work on, as the total gripper height is greatly reduced. Thick pads use more space than thin pads but are able to generate lifting force with a lower air pressure. The choice of which pad to use may be made based on the constraints of the specific tool. FIG. 5 shows various types and configurations of some of the vacuum pads that may be used with the embodiments described herein.

### Standoff Design

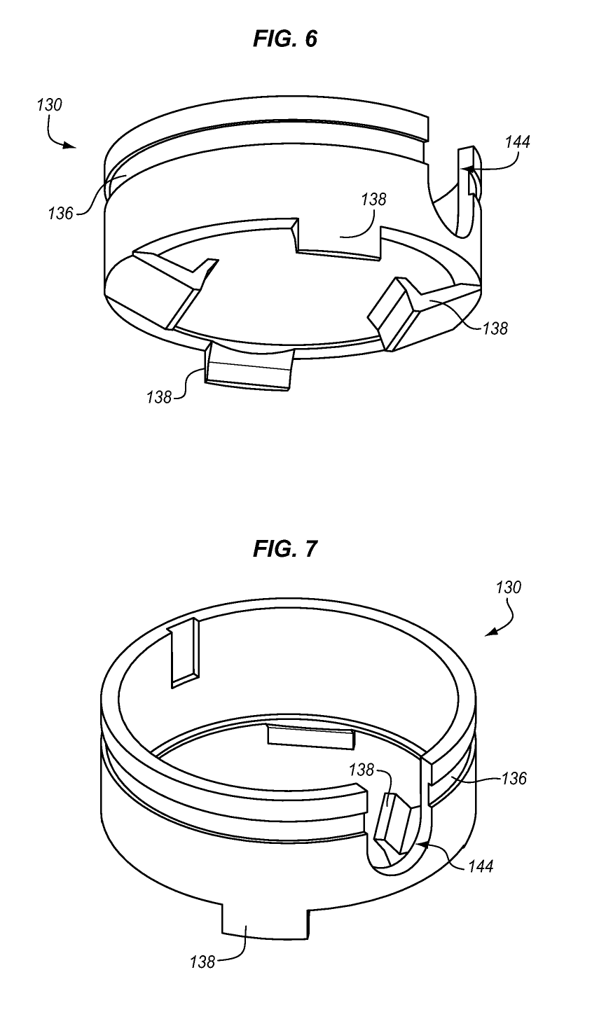

FIG. 6 is an isometric diagram of a standoff 130 as seen from below. FIG. 7 is an isometric diagram of the standoff of FIG. 6 as seen from above. The standoffs may attach to the suction pad via a quick release mechanism 132 (shown in FIGS. 2, 3, and 4, which makes the standoffs easy to replace by an operator or an automatic motion sequence in the machine.

The standoff's upper portion slides around the sides of the vacuum pad and has a groove 136 that mates with the quick release clips. Two or more legs 138 protrude from the bottom of this ring and support the part that is being picked from the edges. A cutout 144 allows unobstructed connection of the air supply from the side, and the inside of the standoff is keyed to guarantee proper rotational alignment relative to the rest of the gripper.

FIG. 8 is an enlarged cross-sectional side view of the standoff of FIG. 6 with the vacuum pad 128 in place to show how a substrate 148 contacts the legs 138 of the standoff 130. Minimal contact is achieved through a chamfered edge leg design. Each supporting leg has a single or double chamfer to guide the part and retain it as the tool transports it to a different location. The other location may be over a circuit board, a test tool, a tray, or a tape.

The double chamfer forms a first smaller angle edge 150 from a normal off the back side surface of the die 148. The first chamfer may be 15° to 40° from the normal or the vertical. The leg then transitions directly as shown or gradually to a larger angle edge 152. This second chamfer may be about 30° to 50° from the normal. The first more vertical edge gently guides the substrate 148 toward the center of the standoff. The second more horizontal edge resists further vertical movement so that the die is aligned roughly horizontally. The edge of the die substrate 148 rests at or close to the transition line between the two chamfers. As shown the legs 138 guide the substrate of the back side of the die 148 into an approximately horizontal position and hold the substrate down against the lifting force of the vacuum pad. The double chamfer may be curved from vertical to horizontal or there may be a single flat surface at one angle, depending on the die and the use of the gripper.

FIG. 8 shows a standoff with four gripper surfaces, although there may be more or fewer. Each surface extends down from the bottom of the standoff and has a double chamfered internal surface. The angle of the internal surface changes at a transition line along each surface. This allows the gripper to contact the edge of a die at a consistent location. The first and lower part of the surface has a tapered angle that is at a lesser angle and closer to the vertical than the second or higher part. The angle of this surface allows the standoff to be aligned over a die. Each angled surface is able to contact an edge of a die as the standoff is lowered over the die. FIG. 1 shows the four edges of the die that are contacted by each gripper.

The die and the standoff are driven into alignment by the angle of the first surface. The second angle is larger or more horizontal. As the standoff is lowered each gripper will slide easily while the die moves along the first part of the surface which is more vertical. Each gripper surface will then provide much more vertical resistance as the die reaches the part of the surface with the second more horizontal angle. Each outer edge of the die will then rest near the junction or transition line between the two different tapers, bevels, or angles. This is the position shown in FIG. 8.

When the standoff is properly aligned, the suction may be applied to the top of the die to hold the die against the gripper surfaces. Alternatively the vacuum may be applied before the die and standoff are in alignment in order to draw the die into position with the gripper surface. With the die held by its edges roughly at the junction between the two tapers of each gripper surface, the gripper may lift away from the die and carry the die to another location. The die is released by releasing the vacuum. The gripper may be operated in a manner similar to a vacuum chuck but does not require a central KOZ. The die may be gripped, held and carried by its edges.

While the direction and forces are shown as vertical and horizontal and described as up and down, these directions are for reference only. The gripper does not rely on gravity or direction. The Bernoulli or cyclone force operates to overcome any gravitational or other directional force as do the legs. Accordingly the tool may be operated sideways or upside down, depending on the particular nature of the work to be performed by the tool.

The standoff may be made in a variety of different shapes and configurations to support application to many different microelectronic devices of different shapes and sizes. In this way the same vacuum pad and tool may be used to pick up different dies. Similarly different vacuum pads may be used to pick up the same die by adapting the standoff.

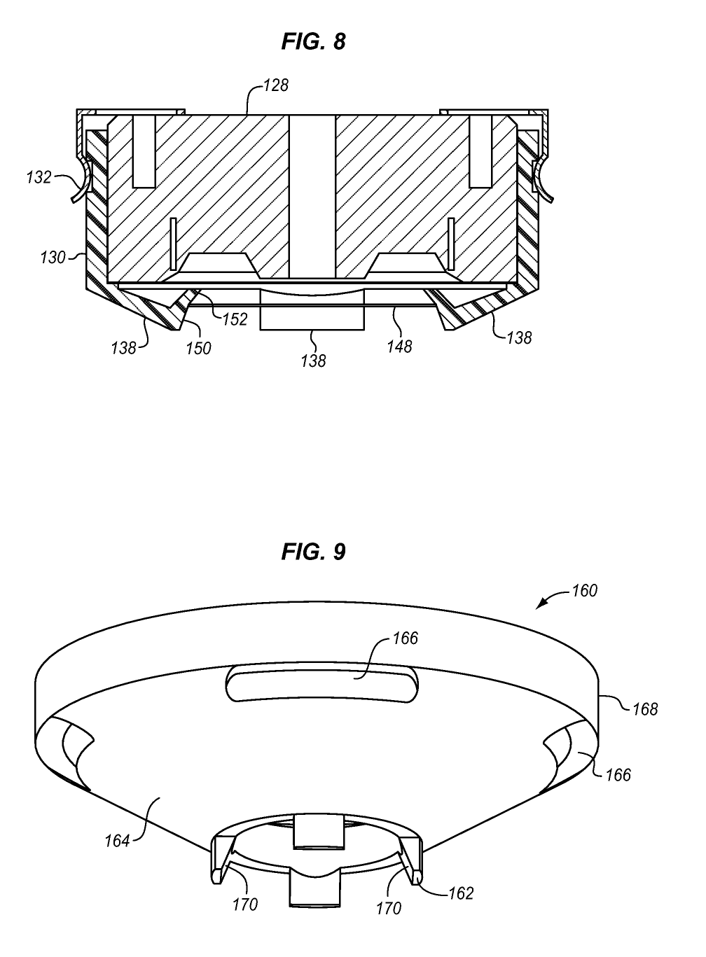

FIG. 9 is an isometric diagram of a bottom view of a standoff 160 for smaller form factor dies. The standoff design may be optimized to prevent the influence of the vortex from the vacuum pad onto the parts in adjacent pockets or other adjacent locations. As shown, the standoff 160 has an outer rim 168 that is configured to mate with a vacuum pad. In this example, the bottom of the vacuum pad may be placed into the outer rim so that the outer rim 168 surrounds or wraps around the vacuum pad. A set of four integral legs 162 extend from the bottom of the standoff to grip a much smaller part. The legs are coupled to the outer rim 168 of the standoff by a funnel shaped bottom surface 164. The outer rim is configured to wrap around the vacuum pad as in the previous examples. The bottom surface reduces the diameter of the standoff at the bottom to suit the smaller, closer positions of the legs 162.

The funnel shape of the bottom surface provides a distance from the vacuum pad to allow the vacuum pad to create a pressure differential to pick up the part. This version of the standoff allows the positive air to exit at the top of the standoff near the outer edge of the vacuum pad via exhaust ports 166. The exhaust ports and the sloped bottom wall preserve the low pressure area in the center of the standoff near the die. The center of the standoff includes an opening in the bottom surface between the legs. This opening is configured to allow the vacuum pad to generate a lifting force on the die. The chamfers 170 of the legs 162 to support the part are displaced to the bottom opening of the cone or funnel to achieve the same zero-KOZ handling. In this example, the legs use a single chamfer edge 170 instead of the double chamfer shown in FIG. 8. The single chamfer or double chamfer edge may be used on any of the standoffs described herein and on variations thereof, depending on the nature of the vacuum pad and the nature of the part to be picked up.

### Quick Release Detail

A variety of different quick release mechanisms may be used to attach the standoff to the vacuum pad. Alternatively, the standoff may be mounted with fasteners that do not release quickly, such as screw, clamps, threaded fittings, and adhesives. FIGS. 3 and 4 show a detail of possible quick release clips 132 as they engage a groove 136 on the standoff. The standoff is removed by pulling straight down. This pulls the tabs 132 of the clips out of the grooves to release the clip. Since the dies are small and light, the standoff does not require a strong attachment. The type of release may be adapted to suit different lifting tasks and different types of devices to be lifted.

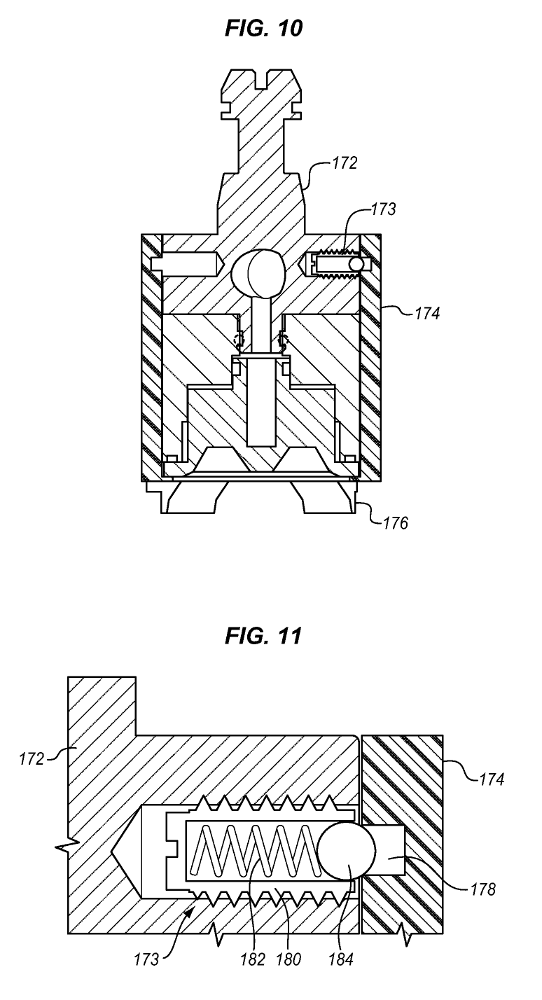

FIG. 10 is a side cross-sectional view of a vacuum pad 172 and a standoff 174 showing another quick-release mechanism 173. The standoff wraps around the vacuum pad and has legs 176 at the bottom surrounding an air chamber to allow the Bernoulli or cyclone effect to be generated by the vacuum pad. The illustrated mechanism uses spring-loaded ball detents attached to the main body of the nozzle or vacuum pad, and a mating groove 178 on the inside of the standoff which allows the spring-loaded ball 184 to click into place.

FIG. 11 is an enlarged cross-sectional side view of a portion of the vacuum pad 172 and standoff 174 to show the ball quick release mechanism 173. A cylinder 180 is screwed into a threaded port on the side of the vacuum pad. While only one is shown there may be two, three, four, or more quick release cylinders around the vacuum pad. The cylinders may all be at the same height or in different positions along the surface of the vacuum pad. The cylinder has a spring 182, in this case a coil spring although embodiments are not so limited, and a ball 184 that is pressed against the inner surface of the standoff by the spring. The ball is held within the cylinder by the end of the spring, tabs or any other desired retention system (not shown).

The standoff has an inner groove 178 or depression to engage the ball 184. The sides of the groove may be straight as shown, curved, or chamfered to allow the ball to move in and out of the groove more easily. The standoff may be removed by pulling the standoff down drawing the edge of the groove against the ball to push the ball into the cylinder against the spring. When the standoff groove moves past the ball, that is when the ball is out of the groove, then the standoff is released.

### Sensor

Part detection may be achieved via an optional reflective sensor whose detection threshold can be adjusted to work with all types of reflective surfaces, such as a bare substrate, a die, a mold, a lid, etc. Two possible mounting options for the sensor include 1) through the body of the nozzle if a fiber optic sensor is used, or 2) directly attached to the bottom of the suction pad if flat LED (Light Emitting Diode) reflective sensors are used. Optical sensors such as LEDs and photodetectors may be used to sense the alignment of the device with the chamfered edges of the legs. Other sensors may also or alternatively be used such as touch, capacitive, and force sensors. Additionally, inline pressure and flow rate sensors may also be used.

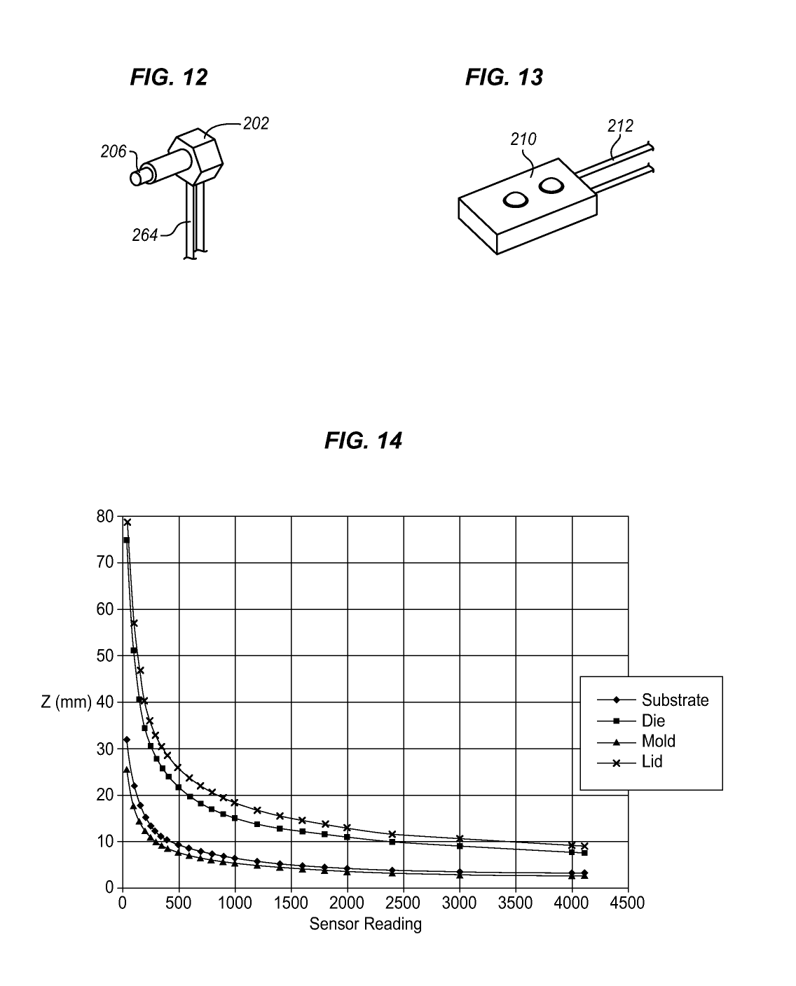

FIG. 12 is a diagram of a fiber optic sensor with a sensor body 202 that contains a sensor, an optic fiber connector 206 connected to the sensor body to conduct light to the sensor, and an electrical connector 204 to receive power, if necessary and connect the sensor output to an external component. The sensor body may be wired to a control system and mounted in a safe location. The optic fiber 206 may extend from the sensor body to a location from which the die can be observed. Multiple fibers or multiple sensors may be used to allow the die to be observed from different location. The sensor body provides a signal when the die has been picked as seen through the fiber.

FIG. 13 is a diagram of a flat LED reflective sensor. The main sensor body 210 has an illuminator and a reflection light sensor. Wire leads 212 provide power to the illuminator and sensor and data form the sensor to the remote control system. The sensor may be mounted where the illuminator and reflection sensor have a clear view of the die when the die has been picked. The sensor may also be used to guide the tool into alignment with the die before the die is picked. These two sensors are provided only as examples. A variety of other sensors may be used, depending on the configuration of the vacuum tool and the standoff and the nature of the die to be picked and placed.

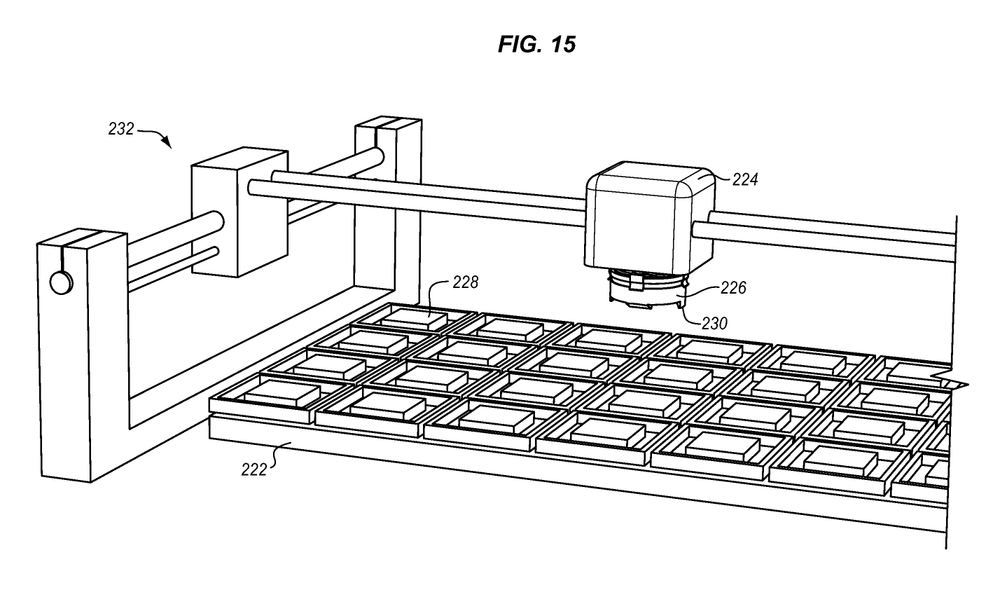

FIG. 14 is a graph of different sensor calibration curves for different possible die surfaces. The distance from a fiber optic sensor is shown on the vertical axis and a sensor reading in terms of the amplitude of the reflected light is shown on the horizontal axis. The curves give sensor readings as a function of distance between the part and the sensor for different types of surfaces: substrate; die; mold; and lid. The sensor is able to detect the parts and the distance to the parts at the short range of 10-20 mm and works on bare substrate, die, lid, or mold. The sensor amplifier can be adjusted to an appropriate threshold level based on the curves or the threshold can be set by calibrating a particular tool if an analog amplifier is used. An LED sensor may also be similarly characterized.

Embodiments may be used for singulated unit handling. Embodiments may also be used for assembly modules in ATTD (Assembly Test/Technology Development) for both single unit and gang pick, as well as strip handling. Embodiments may be adapted to a wide range of different die form factors including: 14×14 mm, 25×25 mm, 40×24 mm and 52.5×52.5 mm, etc. Embodiments may be adapted to tabletop TT (Table Top) pick and place gantry systems, with XYZ motion range sufficient to cover an entire tray, and OFA supply in excess of 90 psi.

FIG. 15 is a side view diagram of a pick and place setup with a 25×25 mm standoff. A tray 220 with multiple compartments 222 rests on a fixture or a work surface. Some or all of the compartments contain a die 228 or other small part. The back side substrate of each die is facing upwards and surrounded by other dies, devices, or other parts on all sides. Each die may be picked up individually and moved to a pocket or processing component on the right (as shown off the page), with OFA pressure of only 14 psi. A motion head 224 carries and powers a vacuum pad that generates the lifting force. A standoff 226 attached to the vacuum pad holds the die in position. A gantry 232 above the vacuum pad provides horizontal and vertical movement to position the vacuum pad as desired to accomplish the movements. The pressure through the vacuum pad may be turned on or off to lift or release each die once the vacuum pad is aligned in position over the intended die.

With the constant demand to shrink packages for the mobile market, the handling KOZ of products is continuously decreasing in size. The current technology available for pick and place is a high risk area for upcoming platforms due to its limited ability to handle products with zero KOZ. Therefore the described solution allows future products to be handled without the persistent die risks of picking.

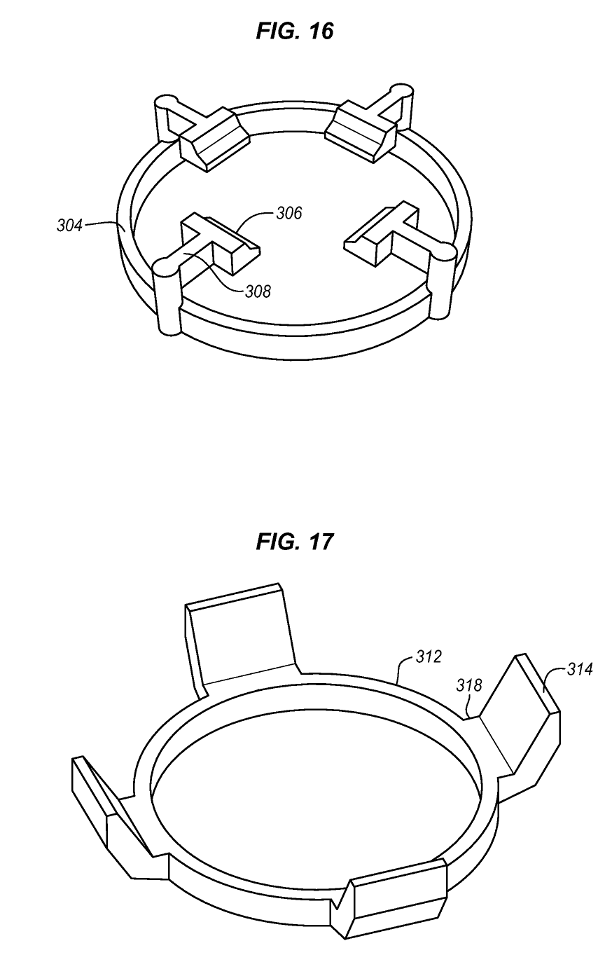

FIG. 16 is an isometric view of an alternative standoff in which the main body 304 is a circular band. The main body does not wrap around and cover the vacuum pad. Instead the main body rests against the bottom edge or the bottom surface of the vacuum pad. This main body defines an opening between the legs through which the vacuum pad may lift a die. The legs 304 are mounted to the main body with integral bars 306. The bars extend from the main body to the legs so that by designing the lengths of the bars, the legs may be in any desired position. As in every other example, the legs may be different distances from the outer rim 304 of the standoff to accommodate dies that are rectangular or in other shapes.

In contrast to the example of FIG. 9, the standoff main body does not have exhaust vents, an air chamber, or any other structure to cooperate with the Bernoulli or cyclone action of the vacuum pad. Instead air flow is controlled entirely by the vacuum pad and the standoff only ensures the position of the die.

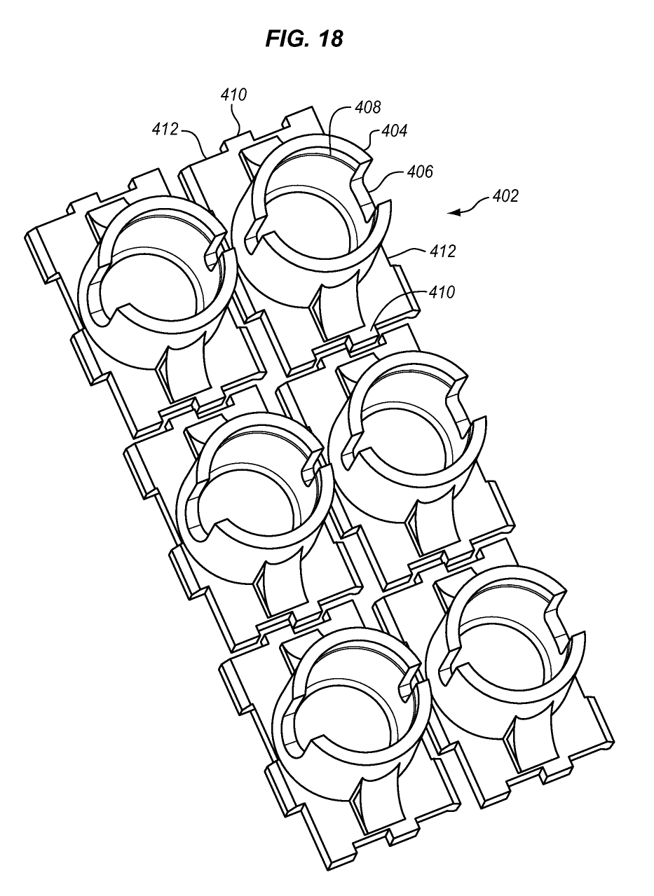

FIG. 17 is an isometric view of another alternative standoff. This standoff shows a similar simple ring-shaped main body 312 that attaches to a bottom or edge surface of the vacuum pad and defines an opening between the legs. The airflow near a workpiece is controlled by the vacuum pad. While the example of FIG. 16 is configured to hold a die that is smaller than the vacuum pad. The example of FIG. 17 is configured to hold a die that is a little larger than the vacuum pad. This may to accommodate different sizes of vacuum pads, different sizes of dies, or both. Legs 314 extend from four positions directly from the main body ring with short bars 318 to translate the positions of the legs outward from the center of the vacuum body. FIG. 16 shows a double chamfer on the legs, while FIG. 17 shows a single chamfer. As in the above embodiments, either standoff type may use either type of leg chamfer.

FIG. 18 is a top isometric view of a set of six standoffs in a position to allow a pick and place head to move six workpieces at a time. While six are shown, more or fewer may be used to suit any particular workflow. With six standoffs, it may be possible to move six dies in the time that would normally be used to move just one. The standoffs 402 are similar to those of FIG. 7 with a large body 404 to wrap around the body of a vacuum pad and a cutout 406 to allow the connection of the air supply. Each standoff has an inner groove 408 for a ball and cylinder quick release to engage and hold each standoff in place on its respective vacuum pad.

The standoffs each have four legs 410 to contact the edge of a die. In this example, the standoff has a rectangular base 412 below the main body. The legs extend from this rectangular base to contact a rectangular die. The size of the base is adapted to suit the size of the intended workpiece.

The legs 410 of each standoff extend past the legs of the adjacent standoff. The legs of a single standoff are shifted to the right on one side and to the left on the opposite side so that, when the standoffs are placed next to each other, the adjacent legs of adjacent standoffs extend farther away from the vacuum pad than the adjacent standoff will allow. The legs are beside each other so that the outer end of each chamfered edge can accommodate a die that is not properly placed for pick up.

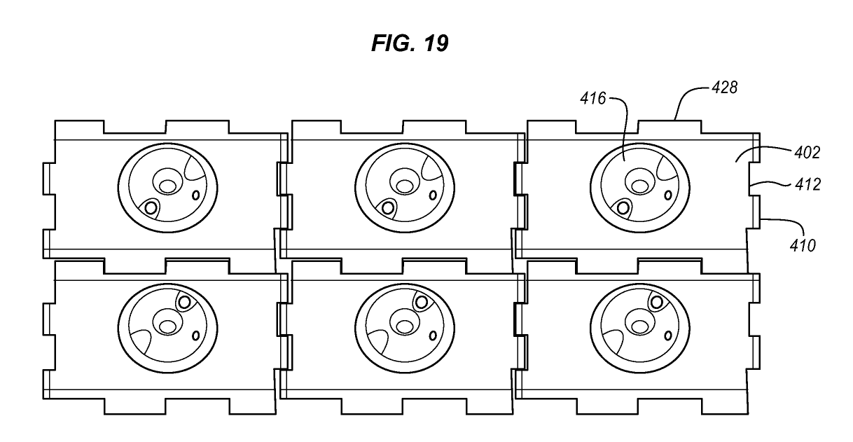

FIG. 19 is a bottom isometric view of the same six standoffs mounted to respective six vacuum pads 428. The vacuum pads are enclosed on the sides by the standoffs 402 but are exposed on the bottom 416 where the Bernoulli or cyclone effect is generated.

As shown, the reach of the standoff legs 410 overlap so that the dies may be very close together and slightly misaligned and yet the legs will guide each die into position with its respective standoff. Each of the four sides of the rectangular bases 412 of each standoff 402 has a leg 410 that extends toward the respective adjacent standoff base. The leg runs beside the corresponding leg of the adjacent standoff to capture the edge of the respective die under each standoff. In use, the six separate vacuum pads 428 may each be operated independently. The vacuum pads may each lift a die at the same time but release a die at different times or vice versa. In this way the pickup head may adjust its position for each pick and for each place independently of each other pick and place. This may be similar to how a single vacuum pad may operate except that when carrying dies from one place to another the carrying time is shared by all six dies.

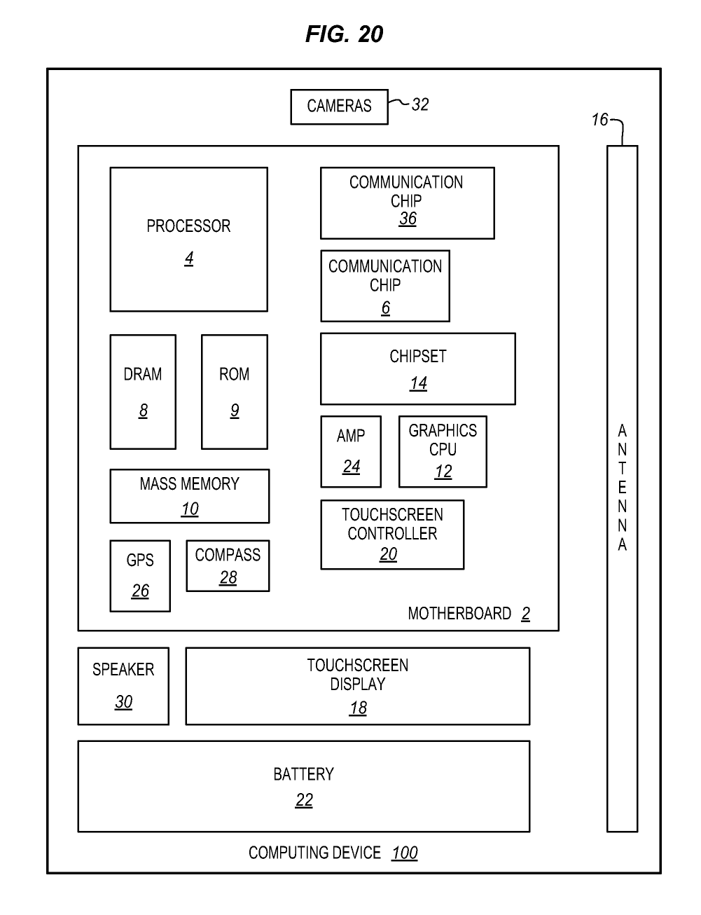

FIG. 20 illustrates a computing device 100 in accordance with one implementation. The computing device 100 houses a board 2. The board 2 may include a number of components, including but not limited to a processor 4 and at least one communication chip 6. The processor 4 is physically and electrically coupled to the board 2. In some implementations the at least one communication chip 6 is also physically and electrically coupled to the board 2. In further implementations, the communication chip 6 is part of the processor 4.

Depending on its applications, computing device 100 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display 18 such as a touchscreen display, a touchscreen controller 20, a battery 22, an audio codec (not shown), a video codec (not shown), a power amplifier 24, a global positioning system (GPS) device 26, a compass 28, an accelerometer (not shown), a gyroscope (not shown), a speaker 30, a camera 32, and a mass storage device (such as hard disk drive) 10, compact disk (CD) (not shown), digital versatile disk (DVD) (not shown), and so forth). These components may be connected to the system board 2, mounted to the system board, or combined with any of the other components.

The communication chip 6 enables wireless and/or wired communications for the transfer of data to and from the computing device 100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 4 of the computing device 100 includes an integrated circuit die packaged within the processor 4. In some implementations, the integrated circuit die of the processor, memory devices, communication devices, or other components include one or more packaged dies and the dies and packages are picked, placed, contacted, or moved using an end effector as described above. The term “processor” may refer to any device or portion of a device that processes electronic data from registers and/or memory to transform that electronic data into other electronic data that may be stored in registers and/or memory.

In various implementations, the computing device 100 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, a digital video recorder, a wearable device, or a node for an Internet of Things (IoT). In further implementations, the computing device 100 may be any other electronic device that processes data.

Embodiments may be adapted to be used with a variety of different types of standoffs with different sizes and configurations for use with various types of testing and assembly equipment for producing the computing system and the various chips of the computing system. A similar computing system may also be used to operate a pick and place machine using the vacuum pads and standoffs as described. References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, the specific location of elements as shown and described herein may be changed and are not limited to what is shown. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to an apparatus that includes a vacuum pad to generate a lifting force and a standoff fastened to the vacuum pad, the standoff having a plurality of legs with chamfered edges to contact the edges of a microelectronic device to hold the device against the lifting force.

In further embodiments the standoff legs are positioned to make contact with the edges of the device.

In further embodiments the standoff is fastened to the vacuum pad with a quick release mechanism.

In further embodiments the standoff legs make only minimal contact along the edges of the device.

In further embodiments the standoff requires no contact on the top of the device.

Further embodiments include a reflective sensor to detect the device.

In further embodiments the reflective sensor is used to align the standoff with the device so that the device can be gripped.

In further embodiments the chamfered edges of the legs guide the device into a position with respect to the vacuum pad before the vacuum pad transports the device to a different location.

In further embodiments the legs each have two chamfer angles to guide the device into a position near the transition line between the two chamfers.

In further embodiments the standoff surrounds the sides of the vacuum pad.

In further embodiments the vacuum pad uses the Bernoulli effect to generate the lifting force to draw the device toward the vacuum pad.

In further embodiments the vacuum pad uses a cyclone to generate the lifting force to draw the device toward the vacuum pad.

In further embodiments the standoff and the legs are formed of single integral piece of material.

In further embodiments the standoff has a funnel shaped bottom surface to preserve a low pressure area from the vacuum pad near the legs.

Further embodiments include exhaust ports in the standoff near the vacuum pad to release positive air pressure.

Further embodiments include a mating adaptor attached to the vacuum pad configure to enable the apparatus to be mounted to a pick and place tool and to support a reflective sensor to sense the device.

Some embodiments pertain to a standoff for a pick and place tool that includes a main body to connect to a vacuum pad, a plurality of legs connected to the main body, the legs each having a chamfered surface each to contact a respective edge of the device, and an opening in the main body between the legs configured to allow a lifting force from the vacuum pad to lift a device.

Some embodiments pertain to a method that includes generating a lifting force on a microelectronic device from a vacuum pad and contacting the edges of the microelectronic device with a plurality of chamfered edges each of a leg of a standoff fastened to the vacuum pad to hold the device against the lifting force.

Further embodiments include detect alignment of the device with the chamfered edges using a reflective optical sensor.

In further embodiments generating a lifting force comprises using the Bernoulli effect.

1. An apparatus comprising:
a vacuum pad to generate a lifting force; and
a standoff fastened to the vacuum pad, the standoff having a plurality of legs with chamfered edges to contact the edges of a microelectronic device to hold the device against the lifting force.

2. The apparatus of claim 1, wherein the standoff legs are positioned to make contact with the edges of the device.

3. The apparatus of claim 1, wherein the standoff is fastened to the vacuum pad with a quick release mechanism.

4. The apparatus of claim 1, wherein the standoff legs make only minimal contact along the edges of the device.

5. The apparatus of claim 1, wherein the standoff requires no contact on the top of the device.

6. The apparatus of claim 1, further comprising a reflective sensor to detect the device.

7. The apparatus of claim 6, wherein the reflective sensor is used to align the standoff with the device so that the device can be gripped.

8. The apparatus of claim 1, wherein the chamfered edges of the legs guide the device into a position with respect to the vacuum pad before the vacuum pad transports the device to a different location.

9. The apparatus of claim 1, wherein the legs each have two chamfer angles to guide the device into a position near the transition line between the two chamfers.

10. The apparatus of claim 1, wherein the standoff surrounds the sides of the vacuum pad.

11. The apparatus of claim 1, wherein the vacuum pad uses the Bernoulli effect to generate the lifting force to draw the device toward the vacuum pad.

12. The apparatus of claim 1, wherein the vacuum pad uses a cyclone to generate the lifting force to draw the device toward the vacuum pad.

13. The apparatus of claim 1, wherein the standoff and the legs are formed of single integral piece of material.

14. The apparatus of claim 1, wherein the standoff has a funnel shaped bottom surface to preserve a low pressure area from the vacuum pad near the legs.

15. The apparatus of claim 14, further comprising exhaust ports in the standoff near the vacuum pad to release positive air pressure.

16. The apparatus of claim 1, further comprising a mating adaptor attached to the vacuum pad configure to enable the apparatus to be mounted to a pick and place tool and to support a reflective sensor to sense the device.

17. A standoff for a pick and place tool comprising:
a main body to connect to a vacuum pad;
a plurality of legs connected to the main body, the legs each having a chamfered surface each to contact a respective edge of the device; and
an opening in the main body between the legs configured to allow a lifting force from the vacuum pad to lift a device.

18. A method comprising:
generating a lifting force on a microelectronic device from a vacuum pad; and
contacting the edges of the microelectronic device with a plurality of chamfered edges each of a leg of a standoff fastened to the vacuum pad to hold the device against the lifting force.

19. The method of claim 18, further comprising detecting alignment of the device with the chamfered edges using a reflective optical sensor.

20. The method of claim 18, wherein generating a lifting force comprises using the Bernoulli effect.
